(19) United States
(12) Patent Application Publication
(10) Pub. No.: US 2011/0180097 A1
(43) Pub. Date: Jul. 28, 2011

(54) THERMAL ISOLATION ASSEMBLIES FOR WAFER TRANSPORT APPARATUS AND METHODS OF USE THEREOF

(75) Inventors: Armin Huseinovic, Medford, MA (US); Ivan L. Berry, Amesbury, MA (US)

(73) Assignee: AXCELIS TECHNOLOGIES, INC., Beverly, MA (US)

(21) Appl. No.: 12/694,597

(22) Filed: Jan. 27, 2010

(51) Int. Cl. G03F 7/42

(52) U.S. Cl. 134/1.2; 156/345.31

(57) ABSTRACT

An apparatus for treating a workpiece, the apparatus comprising a first chamber configured to treat the workpiece at an elevated temperature, the first chamber including an opening for receiving the workpiece; a second chamber in operative communication with the first chamber, the second chamber including an opening for transferring the workpiece to and from the first chamber, wherein the first chamber opening is aligned with the second chamber opening, and wherein a selected one of the first and the second chambers comprises a gate valve configured to selectively open and close access to the first and second chamber openings; and a thermal isolation plate formed of a material effective to substantially prevent heat transfer from the first chamber to the second chamber, wherein the thermal isolation plate is disposed about the first and second chamber openings in a sealing relationship.

### BACKGROUND OF THE INVENTION

The present disclosure generally relates to wafer transport apparatus, and more particularly to thermal isolation plates for a wafer transport apparatus and methods of their use with a plasma ashing apparatus.

Recently, much attention has been focused on developing high-k dielectrics with metal gates to enable scaling of devices. As integrated devices become smaller, scaling of the gate dielectric causes increased leakage due to electron tunneling through the thin dielectric layer. A solution to this problem is to implement a gate dielectric with higher dielectric constant (also referred to as “high k”). As used herein, the term “high k” generally refers to a dielectric constant greater than silicon dioxide. The use of high k dielectric layers as gate insulator layers allow thicker layers to be used, with the thicker high k dielectric layer supplying capacitances equal to thinner silicon oxide layers, or with the high k dielectric layer having an equivalent oxide thickness, equal to the thinner silicon dioxide counterpart layer. Therefore the use of high k dielectric layers, for gate insulator layer, will offer reduced leakage when compared to the thinner silicon dioxide gate insulator counterparts. Additionally, most high-k implementations utilize a metal gate electrode to control the threshold voltage and reduce gate electron carrier depletion.

Many different heavy metal oxides and nitrides have been proposed as higher dielectric constant gate materials to replace the standard silicon oxy-nitride gate dielectrics. Included in the list of proposed replacement dielectrics include oxides and nitrides of Barium (Ba), Dysprosium (Dy), Erbium (Er), Gadolinium (Gd), Hafnium (Hf), Lanthanum (La), Scandium (Sc), Tantalum (Ta), Titanium (Ti), and Zirconium (Zr). Metal gate electrodes proposed include pure metals and carbides and nitrides of Ta, Ti, and Tungsten (W). All of these proposed materials (gate dielectric or gate metal) are sensitive to oxidation or oxidizing environments, which can change the stoichiometry of the oxide, consumption of the metal gate, changes to the gate stack work function, changes in the leakage current, and the like.

In fabricating high-k metal gate devices, two integration schemes have emerged: the Gate First scheme and Gate Last scheme. In the so-called Gate First integration scheme, the metal gate and high-k dielectric can be exposed to photoresist strip and wafer clean processes at the source-drain and source-drain extension ion implantation steps. In the so-called Gate Last integration scheme, the metal gate and high-k dielectric can be exposed to the photoresist strip and clean processes at the contact etch steps. In both schemes, the photoresist strip and wafer clean processes that occur subsequent to the high-k/metal gate deposition must take care not to oxidize either the gate materials, change the stoichiometry of the gate dielectric, and/or oxidize the channel underneath the gate dielectric. Ashing refers to a plasma mediated stripping process by which photoresist and post etch residues are stripped or removed from a substrate upon exposure to the plasma. The ashing process generally occurs after an etching or implant process has been performed in which a photoresist material is used as a mask for etching a pattern into the underlying substrate or for selectively implanting ions into the exposed areas of the substrate. The remaining photoresist and any post etch or post implant residues on the wafer after the etch process or implant process is complete must be removed prior to further processing for numerous reasons generally known to those skilled in the art. The ashing step is typically followed by a wet chemical treatment to remove traces of the ashing residue, which can cause device opens or shorts or lead to an increase in device leakage.

Studies have suggested that a significant shift in the work function and/or change to the transistor drive current of a high-k/metal gate transistor can occur when an oxidizing plasma ash process is used. For example, oxidizing plasma discharges are known to convert metal gate electrodes from the as deposited TiN, for example, into TiO2. Additionally oxidizing plasma discharges can oxidize the silicon conduction channel under the high-k dielectric since most high-k dielectrics are poor diffusion barriers to the oxidizing plasma chemistry and the oxidizing plasmas can change the oxygen content or oxidation state of the high-k dielectric itself. All cases result in degraded transistor performance.

Ideally, the ashing plasma processes should not affect the high-k/metal gate stack or affect the underlying silicon conduction channel and preferentially remove only the photoresist material. In order to minimize damage, substantially non-oxidizing plasma processes have been developed. One such process includes generating plasma from a gas mixture comprising hydrogen and another non-oxidizing gas such as nitrogen, or helium. The mechanism of removal for these less aggressive plasma discharges is significantly different from oxidizing plasmas. The substantially non-oxidizing plasma, such as the plasma formed from nitrogen and hydrogen, does not ash the photoresist in the traditional sense. Rather, it is believed that the hydrogen in the plasma fragments the organic based polymer in the photoresist formulation. These hydrocarbon fragments possess a relatively low vapor pressure as compared to the products obtained after exposure to oxygen containing plasmas, which convert the organic based photoresist into gaseous byproducts such as CO2, CO, H2O and the like. The hydrocarbon fragments possessing the lower vapor pressure have a tendency to condense onto relatively cooler surfaces such as the chamber walls, vacuum lines, valves, pumping lines, pumps, and exhaust conduits. Heating the chamber walls and any other plasma processing components susceptible to the condensation can prevent buildup of the hydrocarbon fragments thereupon. In order to prevent the condensation, the process chamber is often heated to temperatures in excess of 100 degrees Celsius (° C.). Wafer transport apparatus components, however, often have temperature limits well below 100° C.

Moreover, in order to maintain a vacuum seal between the plasma process chamber and the loadlock chamber of the wafer transport apparatus, physical contact between the two components is required. Semiconductor etching, cleaning, and deposition processes are desirably carried out at a reduced pressure, e.g., in an evacuated (vacuum) chamber. It is important to maintain the pressure within the chamber within a specific predetermined range in order to avoid costly delays in the semiconductor wafer production process and to minimize undesirable variations in the quality of the semiconductor wafer products that are produced. Maintaining pressure within the predetermined range is difficult since, during device fabrication, substrates are sequentially fed into the processing chamber in a continuous or batch process from an external source operating at atmospheric conditions. Time spent controlling and readjusting the chamber pressure for each substrate or substrate batch introduced into the processing chamber can greatly increase processing times. The decreased throughput resulting from controlling and readjusting the pressure increases overall device costs. As such, a vacuum seal should exist between the process chamber and the wafer transport apparatus so that substrates can be added and removed from the process chamber without having to pressurize the process chamber each time. Maintaining the vacuum seal, however, typically requires hard metal-to-metal contact between the cold wafer transport assembly and the heated process chamber. This contact permits significant heat flow from the process chamber walls to wafer transfer chamber and its components; as a result, the temperature of these components are raised beyond their safe operating limits. Moreover, the drain of heat from the process chamber wall to the wafer transfer chamber can result in a cold spot on the process chamber wall that permits the return of condensation.

Accordingly, there remains a need for improved processes and devices for thermally isolating the loadlock chamber and wafer transport chamber from the plasma process chamber in the wafer transport apparatus.

### BRIEF SUMMARY OF THE INVENTION

Disclosed herein are processes and devices configured to thermally isolate a wafer transport apparatus from a plasma process chamber.

In one embodiment, an apparatus for treating a workpiece, the apparatus comprises a first chamber configured to treat the workpiece at an elevated temperature, the first chamber including an opening for receiving the workpiece; a second chamber in operative communication with the first chamber, the second chamber including an opening for transferring the workpiece to and from the first chamber, wherein the first chamber opening is aligned with the second chamber opening, and wherein a selected one of the first and the second chambers comprises a gate valve configured to selectively open and close access to the first and second chamber openings; and a thermal isolation plate formed of a material effective to substantially prevent heat transfer from the first chamber to the second chamber, wherein the thermal isolation plate is disposed about the first and second chamber openings in a sealing relationship.

In another embodiment, an apparatus for treating a workpiece comprises a first chamber configured to treat the workpiece at an elevated temperature, the first chamber including an opening for receiving the workpiece; a second chamber in operative communication with the first chamber, the second chamber including an opening for transferring the workpiece to and from the first chamber, wherein the first chamber opening is aligned with the second chamber opening, and wherein a selected one of the first and the second chambers comprises a gate valve configured to selectively open and close access to the first and second chamber openings; and a thermal isolation assembly intermediate and coupled to the first chamber and the second chamber, wherein the thermal isolation assembly comprises a vacuum seal plate disposed about the first chamber opening; and a thermal isolation plate formed of a material effective to substantially prevent heat transfer from the first chamber to the second chamber, wherein the thermal isolation plate is disposed about and abuts the vacuum seal plate.

A process for removing photoresist from a substrate within a wafer transport apparatus includes moving a workpiece from a second chamber to a first chamber, wherein a selected one of the first and the second chambers comprises a gate valve configured to selectively open and close access to the first and second chamber; heating the first chamber to a predetermined temperature effective to substantially prevent hydrocarbon condensation within the first chamber; exposing the workpiece to a plasma in the first chamber; selectively reacting photoresist on the workpiece with the plasma to remove the photoresist from the workpiece and form a semiconductor substrate; thermally isolating the first chamber from the second chamber with a thermal isolation plate formed of a material effective to substantially prevent heat transfer from the first chamber to the second chamber, wherein the thermal isolation plate is disposed about a first and a second chamber openings in a sealing relationship; and removing the semiconductor substrate from the first chamber to the second chamber.

These and other features and advantages of the embodiments of the invention will be more fully understood from the following detailed description of the invention taken together with the accompanying drawings. It is noted that the scope of the claims is defined by the recitations therein and not by the specific discussion of features and advantages set forth in the present description.

### BRIEF DESCRIPTION OF THE DRAWINGS

The following detailed description of the embodiments of the invention can be best understood when read in conjunction with the following figures, which are exemplary embodiments, in which:

FIG. 1 schematically illustrates an embodiment of a wafer transport apparatus including a loadlock chamber and a process chamber;

FIG. 2 schematically illustrates an exploded view of an embodiment of the thermal isolation assembly;

FIG. 3 schematically illustrates a cross-sectional view of the thermal isolation assembly of FIG. 2, shown disposed between a process chamber and a loadlock chamber assembly of a wafer transport apparatus; and

FIG. 4 schematically illustrates a cross-sectional view of another exemplary embodiment of a thermal isolation assembly disposed between a process chamber and a loadlock chamber assembly of a wafer transport apparatus.

Skilled artisans will appreciate that elements in the figures are illustrated for simplicity and clarity and have not necessarily been drawn to scale.

### DETAILED DESCRIPTION OF THE INVENTION

Disclosed herein are thermal isolation assemblies and processes for thermally isolating components of a wafer transport apparatus, and more specifically for thermally isolating a process chamber from a loadlock chamber assembly in the wafer transport apparatus. With respect to photoresist ashing, the processes and devices described herein can effectively prevent or eliminate hydrocarbon buildup within the process chamber while preventing the transfer of heat from the chamber to other components of the wafer transport apparatus. Moreover, the thermal isolation assemblies described herein maintain the desired vacuum seal between the process chamber and loadlock chamber of the wafer transport apparatus. In one embodiment, a thermal isolation assembly comprises a thermal isolation plate disposed between a first chamber (e.g., plasma process chamber) and a second chamber (e.g., loadlock chamber), wherein the thermal isolation plate is formed of a material effective to prevent the flow of heat between the two chambers. In another embodiment, a thermal isolation assembly comprises the thermal isolation plate, and a vacuum seal plate in physical communication with the thermal isolate plate and configured to provide a vacuum seal between the two chambers. As will be described in more detail below, the type of thermal isolation assembly used is determined by the type and design of the process chamber and wafer transport apparatus used in the semiconductor processing system.

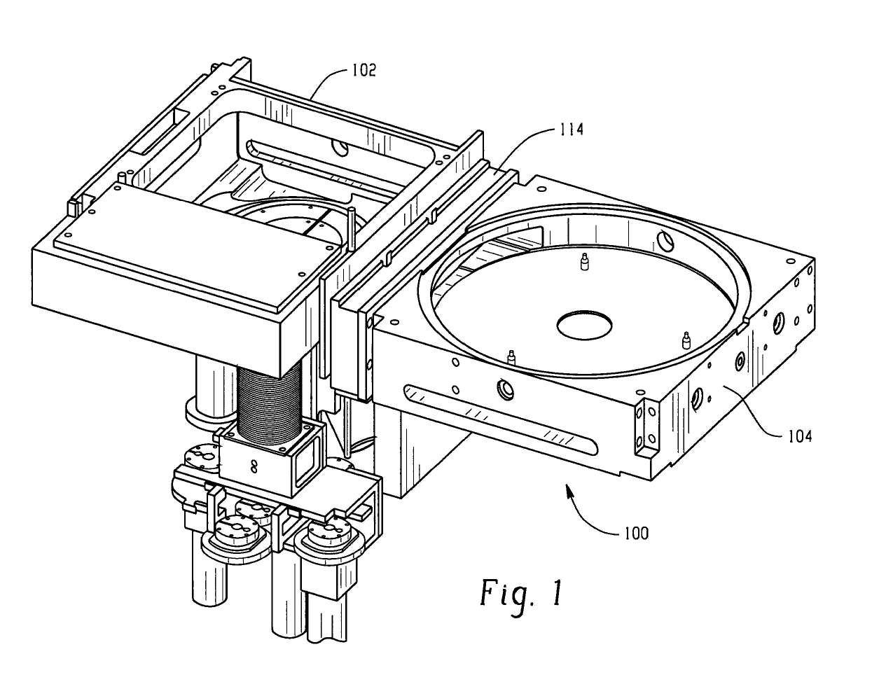

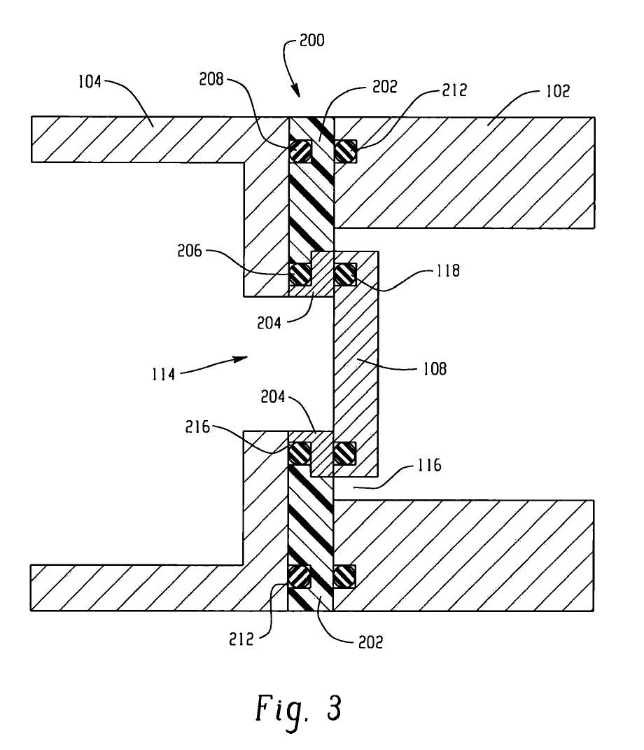

Turning now to FIG. 1, there is shown a perspective view of an apparatus, generally designated by reference numeral 100, which includes a loadlock chamber assembly 102 and a process chamber 104. The apparatus 100 is not intended to be limited to the particular configuration as shown. Other variations and configurations will be apparent to those skilled in the art in view of this disclosure. It is to be understood that the apparatus 100 has been simplified to illustrate only those components that are relevant to an understanding of the present disclosure. Those of ordinary skill in the art will recognize that other components may be required to produce an operational plasma ashing apparatus and wafer transport apparatus. However, because such components are well known in the art, and because they do not further aid in the understanding of the present disclosure, a discussion of such components is not provided. The apparatus 100 for treating a workpiece comprises a first chamber (e.g., the process chamber 104 of a wafer transport apparatus) configured to treat the workpiece at an elevated temperature, the first chamber including an opening 114 for receiving the workpiece. The apparatus 100 further includes a second chamber (e.g., the loadlock chamber 102) in operative communication with the first chamber, the second chamber including an opening 116 for transferring the workpiece to and from the first chamber, wherein the first chamber opening 114 is aligned with the second chamber opening 116, and wherein a selected one of the first and the second chambers comprises a gate valve 108 configured to selectively open and close access to the first and second chamber openings. For example, in FIG. 3, the loadlock chamber assembly 102 is in operative communication with the process chamber 104. Operative communication between the loadlock chamber 102 and the process chamber 104 permits wafer exchange between the chambers to occur without elevating the pressure within the process chamber. While active wafers are processed in the evacuated process chamber 104, e.g., plasma mediated processing, the loadlock chamber 102 is vented to the atmosphere to allow additional wafers to be queued and loaded into the loadlock chamber. Once the queued wafers are loaded into the loadlock chamber 102, the loadlock chamber pressure is reduced to the operating pressure of the processing chamber 104. After processing of the active wafers in the process chamber 104 is complete, the active wafers are then removed and exchanged with the queued wafers in the loadlock chamber 102. The queued wafers are then processed accordingly in the processing chamber and the previously processed active wafers removed from the loadlock chamber and exchanged with additional wafers to be processed. The cycle may then be repeated as necessary.

The loadlock assembly 102 and the process chamber 104 are interconnected, wherein a closable vacuum sealed opening 114 is disposed and configured for permitting the exchange of wafers between the two chambers. The opening 114, as shown, is configured for permitting a single wafer to be passed therethrough. Alternatively, opening 114 may be sized and configured to allow two or more wafers to simultaneously pass through, e.g., a processed wafer exiting the process chamber and an unprocessed wafer entering the process chamber. The process chamber 104 is separated from the loadloack chamber assembly 102 by a gate valve (not shown in FIG. 1).

The operating pressures within the process chamber 104 are about 1 millitorr to about 10 torr; specifically about 200 millitorr to about 2 ton; and more specifically about 500 millitorr to about 1.5 torr.

To substantially prevent hydrocarbon buildup, surfaces that are exposed to the volatile photoresist, ashing byproducts, and the like during processing are heated. For example, the process chamber walls, e.g., bottom wall, top wall, and sidewalls, can be heated during substantially non-oxidizing plasma processing. In one embodiment, the process chamber walls are heated to greater than 60° C. to substantially prevent hydrocarbon buildup, and in other embodiments, the process chamber walls are heated to greater than 100° C. At chamber wall temperatures greater than 100° C., hydrocarbon buildup within the interior of the process chamber 104 was found to be completely eliminated. Heating of the process chamber walls can be caused by resistive heating, lamp heating, induction heating, or the like, the manner of which is well within the skill of those in the art. Optionally, the process chamber walls may be thermally insulated to minimize heat loss and increase thermal uniformity of the chamber's internal walls. Insulating the walls of the process chamber 104 can increase thermal uniformity of the chamber's internal walls, provide protection of sensitive components, and increase efficiency by lowering power usage, among others. Still further, in some applications, the process chamber may be cooled in the event the process chamber surfaces are too hot for a given process. In these embodiments, the process chamber may further include an active temperature control system for regulating temperature of the process chamber walls. For cooling, the process chamber may be configured with fluid passages, and the like.

The thermal isolation assemblies described herein are configured to be used with apparatuses employing substantially non-oxidizing plasma processing. The devices can be disposed between a heated plasma process chamber and an unheated wafer transport apparatus. The thermal isolation assembly provides a thermal barrier to substantially prevent the flow of the heat from the process chamber walls to the wafer transport apparatus components, such as the loadlock chamber. The thermal isolation assembly, therefore, prevents cold spots from developing on the process chamber walls where heat has escaped and prevents overheating (and potentially damage) to the wafer transfer apparatus components.

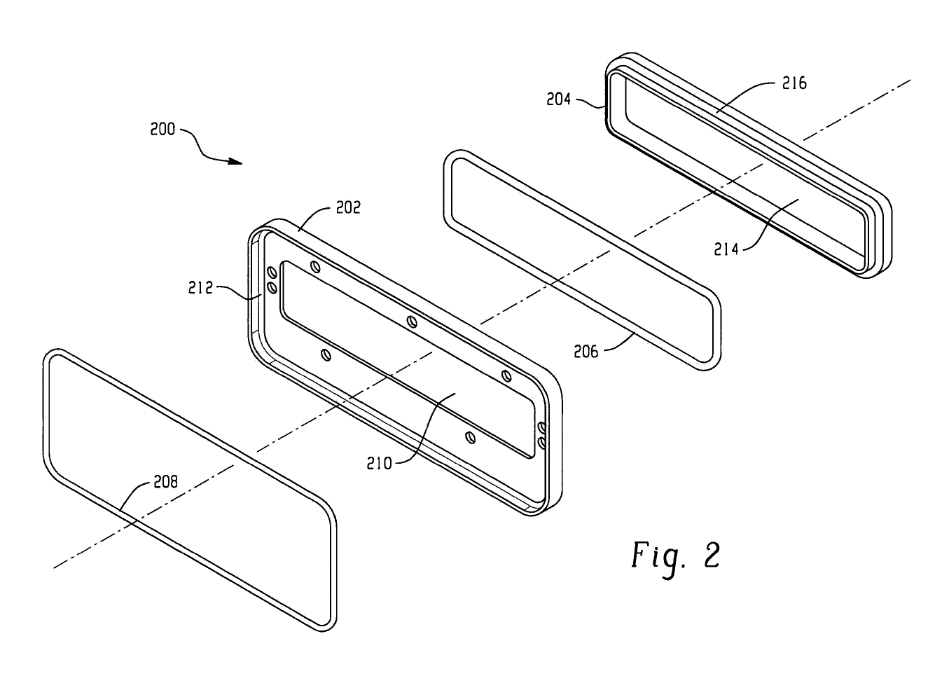

Turning now to FIGS. 2-3, an exemplary embodiment of a thermal isolation assembly 200 for use with the apparatus 100 is shown. FIG. 2 illustrates an exploded view of the thermal isolation assembly 200. The device comprises a thermal isolation plate 202 and a vacuum seal plate 204. A first O-ring 206 is disposed between the thermal isolation plate 202 and the vacuum seal plate 204 to seal the two plates. A second O-ring 208 is disposed between the thermal isolation plate and the process chamber 104 at the opening 114 to provide a seal between the thermal isolation assembly 200 and the process chamber 104. FIG. 3 shows a cross-sectional view of the thermal isolation assembly 200 disposed in operative communication between the process chamber 104 and the loadlock chamber assembly 102 of the apparatus 100.

The thermal isolation plate 202 is configured to thermally isolate the process chamber 104 from the loadlock chamber assembly 102 of the wafer transport apparatus 100. As such, the thermal isolation plate 202 is disposed between the two chambers to prevent thermal conduction from the heated process chamber walls to the unheated loadloack chamber assembly. The vacuum seal plate 204 is configured to provide a vacuum seal between the two chambers when the thermal isolation assembly is disposed therebetween. Additionally, the vacuum seal plate can be made from a plasma resistant material such as aluminum or stainless steel since it has minimal thermal contact to the heated process chamber 104. As shown in FIG. 3, the vacuum seal plate 204 is disposed between the portion of the process chamber wall that defines the opening 114 and the gate valve 108 of the loadlock chamber assembly 102. The first O-ring 206 is configured to seal the vacuum seal plate 204 to the thermal isolation plate 202. The second O-ring 208 is disposed about a periphery of the thermal isolation plate 202 and is configured to seal the thermal isolation assembly 200 with the process chamber 104. A third O-ring 112 is disposed around a periphery of the loadlock chamber assembly 102 and is configured to seal the thermal isolation assembly 200 to the loadlock chamber. A fourth O-ring 118 can also be used to form a seal between the thermal isolation assembly 200 and the gate valve 108.

The thermal isolation plate 202 is advantageously comprised of a polymer configured to thermally isolate the two chambers of the apparatus 100. Generally, it is desirable to have at least a 40° C. drop across the two chambers of the apparatus 100. Therefore, an exemplary polymer for use as the thermal isolation plate 202 will have a low thermal conductivity sufficient to provide an adequate thermal barrier that satisfies the minimum temperature drop requirement. The low thermal conductivity of the polymer allows for a much thinner isolation plate than would be possible if a metallic isolation plate were used. In one embodiment, the thermal isolation plate has a thickness of about 0.5 centimeters (cm) to about 5 cm; specifically about 0.75 cm to about 2.5 cm. The actual thickness for a given isolation plate will depend upon the type of polymer chosen for the plate and the thermal conductivity of that polymer. Exemplary polymers will have a thermal conductivity of about 0.05 Watts per meter per Kelvin (W/m/K) to about 20 W/m/K; specifically about 0.1 W/m/K to about 0.5 W/m/K; and more specifically about 0.1 W/m/K to about 0.3 W/m/K. Exemplary polymers can include, without limitation, polyimide (PI), polyetheretherketone (PEEK), polyetherimide (PEI), polyamidimide (PAI), polyethylene terephthalate (PET), polyethylene naphthalate (PEN), polycyclohexylene terephthallate (PCT), and other like thermally insulating materials. In one embodiment, the thermal isolation plate 202 can be formed of PEI, such as Ultem® 1000 commercially available from SABIC Innovative Plastics. In another embodiment, the thermal isolation plate 202 can be formed of PEEK, such as that produced by Victrex®.

Again, the thermal isolation assembly 200, using the polymer thermal isolation plate 202, is configured to thermally isolate the two chambers of the apparatus 100. The polymer thermal isolation plate 202 can have any size and shape suitable for thermally isolating the process chamber 104 from the loadlock chamber assembly 102. The shape of the isolation plate 202 can generally corresponds to the outer shape of the process chamber 104 and/or the loadlock chamber assembly 102. In one embodiment, for example, the isolation plate 202 has a rectangular shape with a height and width that matches the height and width of the two chambers. The thermal isolation plate 202 further includes an aperture 210 that corresponds with the opening 114 between the two chambers such that the opening 114 is unobstructed when the thermal isolation assembly 200 is disposed within the apparatus 100 and one or more wafers can pass unimpeded from one chamber to the other. Like the overall shape of the isolation plate 202, the aperture 210 has a size and shape that corresponds to the size and shape of the opening 114 between the two chambers. In the embodiment of FIG. 2, the aperture 210 is disposed in the upper third of the isolation plate 202 to correspond with the location in the opening 114 in the process chamber wall and the corresponding opening in the sidewall of the loadlock chamber assembly 102. In another embodiment, the aperture 210 can be disposed in a different location of the isolation plate 202 to correspond with the vertical location of the opening between the two chambers. The thermal isolation plate 202 further includes a channel 212 or recess disposed about the periphery of the plate on the surface configured to be in physical communication with the process chamber 104. In other words, the channel 212 is disposed on a surface of the isolation plate 202 opposite the side in which the vacuum seal plate 204 is disposed. The channel 212 is configured to receive the second O-ring 208 and provide a vacuum seal between process chamber 104 and the thermal isolation assembly 200.

The polymer composition of the thermal isolation plate 202 advantageously allows the process chamber 104 to be operatively coupled to the loadlock chamber assembly 102 without the heat from the process chamber walls flowing to the unheated loadlock chamber. The polymer materials described herein have the sufficiently low thermal conductivities required to make an adequate thermal barrier between the two chambers. Unfortunately, some of these polymer materials have other drawbacks that can affect the operability of the apparatus 100. One of the main drawbacks is the poor vacuum characteristics of the polymer material. The polymers described herein can have stability issues under vacuum conditions and can suffer from outgassing. Another drawback is that some of the polymers described herein may react with the non-oxidizing plasmas used to remove the organics from the substrates. In order to alleviate at least these drawbacks, the vacuum seal plate 204 is used in combination with the thermal isolation plate 202 to form the thermal isolation assembly 200. While the thermal isolation plate 202 provides the mechanical interface between the two chambers, the vacuum seal plate 204 provides the vacuum sealing component. As shown in FIG. 3, the vacuum seal plate 204 is in physical communication with opening 114 in the plasma chamber and the gate valve 108 of the loadlock chamber assembly. As such, the metal vacuum seal plate 204 shields the thermal isolation plate 202 from exposure to the non-oxidizing plasma in the process chamber and maintains the vacuum seal between the process chamber 104 and the loadlock chamber 102 when the gate valve 108 is opened. Moreover, the face of the vacuum seal plate 204 in contact with the plasma chamber 104 is optimized so as to minimize the area of contact for heat transfer between the plate and the chamber, yet to allow enough protection from over compressing or pinching of the o-ring 216. The vacuum seal plate 204 is not in physical communication with the loadlock chamber assembly walls 106. Virtually no heat from the process chamber walls, therefore, can transfer through the vacuum seal plate 204 and into the loadlock chamber assembly 102.

The vacuum seal plate 204 has a size and shape configured to seal the thermal isolation plate 202. A portion of the vacuum seal plate 204 is configured to be mate with the thermal isolation plate by insertion into the aperture 210 of the thermal isolation plate. The vacuum seal plate includes an aperture 214 formed in the plate so that when in physical communication with the thermal isolation plate 202 the like apertures (210 and 214) are coaxially aligned, thereby permitting passage of the work substrate between the two chambers through the opening 114. In one embodiment the vacuum seal plate 204 further includes a channel 216 or recess disposed about the periphery of the aperture 214 and configured to receive the first O-ring 206. The outer edge of the thermal isolation plate 202 can further include a concave or beveled edge configured to receive the first O-ring 206 when the vacuum seal plate is placed in physical communication with the thermal isolation plate 202 to form the thermal isolation assembly 200. The vacuum seal plate 204 can comprise any metal capable of withstanding the reduced pressure of the process chamber, and that will not react with the non-oxidizing plasmas used therein. Exemplary metals can include, without limitation, stainless steel, aluminum, titanium, nickel, alloys thereof, and the like. In one embodiment, the vacuum seal plate 204 can be formed of an aluminum alloy, such as type 6061. In another embodiment, the vacuum seal plate 204 can be further coated with a non-copper containing material to provide protection at temperatures greater than 100° C. Optionally, the aluminum alloy can be anodized prior to deposition of the non-copper containing coating. Exemplary coating materials include, without limitation, silicon carbide (SiC), silicon oxynitride (SiON), tantalum (Ta), tantalum nitride (TaN), titanium nitride (TiN), silicon oxycarbide (SiOC), aluminum oxide (Al2O3), pure aluminum, silicon nitride, and the like

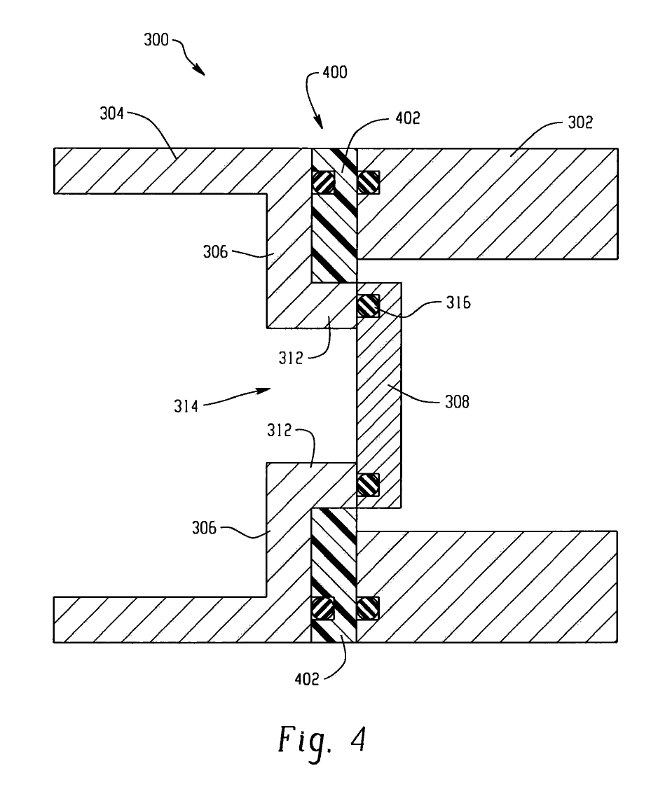

Turning now to FIG. 4, another exemplary embodiment of a wafer transport apparatus, generally designated by reference numeral 300, which includes a loadlock chamber assembly 302 and a process chamber 304, is shown. In this embodiment, a thermal isolation assembly 400 is disposed between the process chamber 304 and the loadlock chamber assembly 302. Unlike the thermal isolation assembly 200 described above, the thermal isolation plate 400 of FIG. 4 comprises only a thermal isolation plate 402. The vacuum seal plate is eliminated in this embodiment by incorporating it into the design of the plasma chamber 304. The process chamber side wall 306, which comprises an opening 314 through which one or more wafers can pass, has a lip feature integrated around the opening 314 that is polished for vacuum-type seal and is in physical communication with the gate valve 308 and the thermal isolation plate 402. The lip 312 protects the thermal isolation plate 402 from exposure to non-oxidizing plasmas in the process chamber 304. Moreover, an O-ring 316 disposed between the gate valve 308 and the lip 312 is configured to provide a vacuum seal between the process chamber 304 and the loadlock chamber assembly 302. As such, the vacuum seal will not be susceptible to possible stability and outgassing problems from the thermal isolation plate 402. The thermal isolation plate 402 is configured to be in physical communication with the process chamber side wall 306, the lip 312, and the loadlock chamber assembly 302. The thermal isolation plate 402 comprises an aperture configured so that when in physical communication with the process chamber 304 the aperture and the opening 314 are aligned, thereby permitting passage of the work substrate between the two chambers. The aperture 404 is configured to be disposed about the outer perimeter of the lip 312. The process chamber sidewall design provides an integrated metal vacuum seal to ensure pressure stability between the two chambers, while the thermal isolation assembly 400 disposed in between the two chambers prevents the transfer of heat from the process chamber to the other components of the wafer transport apparatus 300.

The thermal isolation assemblies as described herein are intended for use with apparatuses (e.g., plasma treatment devices) that employ substantially non-oxidizing plasma processing of a semiconductor workpiece (i.e., substrate or wafer) so as to remove organic matter therefrom, e.g., photoresist, photoresist ashing byproducts, post etch residues, and the like. The substantially non-oxidizing plasmas for ashing photoresist are typically hydrogen-containing gas mixtures, but other non-hydrogen-containing gases have been shown to also be substantially non-oxidizing, including but not limited to N₂O and CO. Exemplary substantially non-oxidizing plasmas are disclosed in U.S. Patent Publication No. 2009/0277871A1 entitled, Plasma Mediated Ashing Processes That Include Formation of a Protection Layer Before and/or During the Plasma Mediated Ashing Process, and in U.S. patent application Ser. No. 12/275,394 entitled, Front End of Line Plasma Mediated Ashing Processes and Apparatus, both of which are incorporated herein by reference in their entireties. The particular components of the plasma gas mixture are selected by their ability to form a gas and plasma at plasma forming conditions. The gas mixture selected is substantially free from components that generate reactive oxygen species in excess of non-oxidizing reactive species at plasma forming conditions. The gas mixture may include reactive gases such as a hydrogen-bearing gas, a nitrogen-bearing gas, a fluorine-bearing gas, a chlorine-bearing gas, a bromine-bearing gas, and mixtures thereof. The gas mixture may further comprise an inert gas such as argon, helium, neon, and the like. The plasma generated from these gas mixtures primarily reacts with carbon and other atoms within the photoresist, polymers, and residues to form somewhat volatile and/or sublimable compounds and/or rinse-removable compounds. The term “substantially” as used herein generally refers to plasma gas mixtures that form plasmas wherein the non-oxidizing reactant concentration greatly exceeds the oxidizing reactants. By way of example, a substantially non-oxidizing plasma gas mixture is a mixture of NH₃ and O₂, wherein the volumetric concentration of O₂ is less than 30%. In many instances, it may be beneficial to add a small amount of oxygen gas to the substantially non-oxidizing plasma to increase ashing rate as well as to inhibit copper hydride formation in process chambers formed of an aluminum alloy having a small percentage of copper within the alloy composition.

Hydrogen-bearing gases suitable for use in the substantially non-oxidizing plasma process include those compounds that contain hydrogen. The hydrogen-bearing gases include hydrocarbons, hydrofluorocarbons, hydrogen gas, ammonia, hydrides, or mixtures thereof. Exemplary hydrogen-bearing gases exist in a gaseous state at plasma forming conditions and release hydrogen to form reactive hydrogen such as atomic hydrogen and excited state molecular hydrogen species under plasma forming conditions. The hydrocarbons or hydrofluorocarbons are generally unsubstituted or may be partially substituted with a halogen such as bromine, chlorine or fluorine. Examples of hydrogen-bearing hydrocarbon gases include methane, ethane and propane.

Hydrogen-bearing gases may be composed of mixtures of a hydrogen gas and a noble gas or nitrogen. Examples of noble gases suitable for use in the process include a gas in Group VIII of the periodic table such as argon, neon, helium, nitrogen, and the like. Particularly exemplary for use in the present invention is a gas mixture that includes a hydrogen bearing gas and a nitrogen bearing gas.

Halogen-bearing compounds in the plasma are less than about 10 percent of the total volume of the plasma gas mixture to maximize selectivity. When the fluorine compounds, for example, are greater than about 10 percent by volume, polymerization of the photoresist byproducts can occur making the polymerized photoresist more difficult to remove. Exemplary halogen compounds include those compounds that generate halogen reactive species when excited by the plasma. Preferably, the halogen compound is a gas at plasma forming conditions and is selected from the group consisting of a compound having the general formula CₓH_{y}A_{z}, wherein A represents a halogen such as F, Cl, Br or I, x ranges from 1 to 4, y ranges from 0 to 9 and z ranges from 1 to 10, HF, F₂, HCl, HBr, Cl₂, Br₂, and SF₆. Other halogen bearing compounds that do not generate reactive substantial amounts of oxygen species will be apparent to those skilled in the art. More preferably, the halogen-bearing compound is CF₄, C₂F₆, CHF₃, CH₂F₂, CH₃F or mixtures thereof.

To prevent the reduction of metal nitrides or silicides, a reduction suppression gas containing a nitrogen bearing gas may be added to the substantially non-oxidizing gas or gas mixture. Preferably, the nitrogen bearing gas is N₂, NH₃, NO, NO₂, and/or N₂O. In the case of NH₃, this can also function as the source for both the nitrogen bearing gas and the hydrogen bearing substantially non-oxidizing gas.

In operation, a semiconductor wafer with photoresist, ion implanted photoresist residues and/or post etch residues thereon (and an oxidation sensitive material such as a high-k dielectric, metal gate or the like) is placed into the process chamber on the wafer pedestal. The workpiece is preferably heated, such as by infrared lamps or a thermally heated chuck to accelerate the reaction of the photoresist and/or post etch residues with the plasma. The pressure within the process chamber is then reduced. Preferably, the pressure within the process chamber is maintained between about 0.1 torr to about 5 torr. An excitable substantially non-oxidizing plasma gas mixture is then fed into a plasma-generating component. Depending on the application, the charged particles may be selectively removed before the plasma enters the process chamber. The plasma chamber is heated to a temperature of about 60° C. to about 160° C. to prevent hydrocarbon buildup (i.e. condensation) on the process chamber walls and components once the plasma enters the process chamber. A thermal isolation assembly is disposed between the process chamber and a wafer transport apparatus to prevent the thermal conduction of this heat from the process chamber walls into the wafer transport apparatus components, such as the loadlock chamber. Moreover, a vacuum seal plate, or the process chamber sidewall design (i.e., the opening lip feature), will prevent exposure of the thermal isolation plate to the non-oxidizing plasma and maintain the pressure in the process chamber. The excited or energetic atoms of the gas are then fed into the process chamber and uniformly expose the workpiece where, for example, atomic hydrogen species react with the photoresist and/or post etch residues, which causes removal of the photoresist material and also forms somewhat volatile byproducts. The photoresist material and volatile byproducts are continuously swept away from the workpiece surface to an exhaust conduit assembly.

The thermal isolation assembly when used with the apparatus 100 overcomes many of the problems noted in the prior art as it relates to processing substrates with substantially non-oxidizing plasma discharges, and in particular, hydrocarbon condensation, and undesired thermal conduction between components, among others

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the embodiments of the invention belong. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

While embodiments of the invention have been described with reference to exemplary embodiments, it will be understood by those skilled in the art that various changes can be made and equivalents can be substituted for elements thereof without departing from the scope of the embodiments of the invention. In addition, many modifications can be made to adapt a particular situation or material to the teachings of embodiments of the invention without departing from the essential scope thereof. Therefore, it is intended that the embodiments of the invention not be limited to the particular embodiment disclosed as the best mode contemplated for carrying out this invention, but that the embodiments of the invention will include all embodiments falling within the scope of the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. An apparatus for treating a workpiece, the apparatus comprising:
a first chamber configured to treat the workpiece at an elevated temperature, the first chamber including an opening for receiving the workpiece;
a second chamber in operative communication with the first chamber, the second chamber including an opening for transferring the workpiece to and from the first chamber, wherein the first chamber opening is aligned with the second chamber opening, and wherein a selected one of the first and the second chambers comprises a gate valve configured to selectively open and close access to the first and second chamber openings; and
a thermal isolation plate formed of a material effective to substantially prevent heat transfer from the first chamber to the second chamber, wherein the thermal isolation plate is disposed about the first and second chamber openings in a sealing relationship.

2. The apparatus of claim 1, wherein the first chamber opening includes a lip circumscribing the opening and the thermal isolation plate abuts the lip.

3. The apparatus of claim 1, further comprising a vacuum seal plate disposed about the first chamber opening, wherein the thermal isolation plate abuts the vacuum seal plate.

4. The apparatus of claim 3, wherein the vacuum seal plate is configured to prevent exposure of the thermal isolation plate to an operating environment of the first chamber.

5. The apparatus of claim 1, wherein the thermal isolation plate is a polymer.

6. The apparatus of claim 5, wherein the polymer has a thermal conductivity of about 0.05 Watts per meter Kelvin to about 20 Watts per meter Kelvin.

7. The apparatus of claim 3, wherein the vacuum seal plate is formed of aluminum or other metal alloy.

8. The apparatus of claim 1, wherein an O-ring is disposed between the thermal isolation plate and the first chamber to provide an airtight seal therebetween.

9. The apparatus of claim 3, wherein an O-ring is disposed between the thermal isolation plate and the vacuum seal plate in a sealing relationship.

10. The apparatus of claim 1, wherein the first chamber is a process chamber configured to receive a plasma.

11. The apparatus of claim 1, wherein the second chamber is a wafer transfer chamber or a loadlock chamber assembly.

12. The apparatus of claim 10, wherein the process chamber comprises a top wall, a bottom wall, and side walls extending therebetween, and wherein at least one wall is heated to a predetermined temperature.

13. An apparatus for treating a workpiece, the apparatus comprising:
a first chamber configured to treat the workpiece at an elevated temperature, the first chamber including an opening for receiving the workpiece;
a second chamber in operative communication with the first chamber, the second chamber including an opening for transferring the workpiece to and from the first chamber, wherein the first chamber opening is aligned with the second chamber opening, and wherein a selected one of the first and the second chambers comprises a gate valve configured to selectively open and close access to the first and second chamber openings; and
a thermal isolation assembly intermediate and coupled to the first chamber and the second chamber, wherein the thermal isolation assembly comprises
a vacuum seal plate disposed about the first chamber opening; and
a thermal isolation plate formed of a material effective to substantially prevent heat transfer from the first chamber to the second chamber, wherein the thermal isolation plate is disposed about and abuts the vacuum seal plate.

14. The apparatus of claim 13, wherein the vacuum seal plate is configured to prevent exposure of the thermal isolation plate to an operating environment of the first chamber.

15. The apparatus of claim 13, wherein the thermal isolation plate is a polymer.

16. The apparatus of claim 15, wherein the polymer has a thermal conductivity of about 0.05 Watts per meter Kelvin to about 20 Watts per meter Kelvin.

17. The apparatus of claim 13, wherein the vacuum seal plate is formed of aluminum or other metal alloy.

18. The apparatus of claim 13, wherein an O-ring is disposed between the thermal isolation plate and the first chamber to provide an airtight seal therebetween.

19. The apparatus of claim 13, wherein an O-ring is disposed between the thermal isolation plate and the vacuum seal plate to provide an airtight seal therebetween.

20. The apparatus of claim 13, wherein the first chamber is a process chamber configured to receive a plasma.

21. The apparatus of claim 20, wherein the plasma is a substantially non-oxidizing plasma.

22. The apparatus of claim 21, wherein the process chamber comprises a top wall, a bottom wall, and side walls extending therebetween, and wherein at least one wall is heated to a predetermined temperature.

23. The apparatus of claim 13, wherein the second chamber is a loadlock chamber assembly.

24. The apparatus of claim 17, wherein the vacuum seal plate is coated with a non-copper containing material.

25. The apparatus of claim 24, wherein the non-copper containing material comprises silicon carbide, silicon oxynitride, tantalum, tantalum nitride, titanium nitride, silicon oxycarbide, aluminum oxide, pure aluminum, silicon nitride, or a combination comprising at least one of the foregoing.

26. A process for removing photoresist from a substrate within a wafer transport apparatus, comprising:
moving a workpiece from a second chamber to a first chamber, wherein a selected one of the first and the second chambers comprises a gate valve configured to selectively open and close access to the first and second chamber;
heating the first chamber to a predetermined temperature effective to substantially prevent hydrocarbon condensation within the first chamber;
exposing the workpiece to a plasma in the first chamber;
selectively reacting photoresist on the workpiece with the plasma to remove the photoresist from the workpiece and form a semiconductor substrate;
thermally isolating the first chamber from the second chamber with a thermal isolation plate formed of a material effective to substantially prevent heat transfer from the first chamber to the second chamber, wherein the thermal isolation plate is disposed about a first and a second chamber openings in a sealing relationship; and
removing the semiconductor substrate from the first chamber to the second chamber.

27. The process of claim 26, wherein the plasma is a substantially non-oxidizing plasma.

28. The process of claim 26, further comprising preventing exposure of the thermal isolation plate to the plasma in the first chamber with a vacuum seal plate disposed about the first chamber opening, wherein the thermal isolation plate abuts the vacuum seal plate.

29. The process of claim 26, wherein the thermal isolation plate is a polymer.

30. The process of claim 29, wherein the polymer has a thermal conductivity of about 0.05 Watts per meter Kelvin to about 20 Watts per meter Kelvin.

31. The process of claim 26, wherein the vacuum seal plate is formed of aluminum or other metal alloy.
